(19) United States
(12) Patent Application Publication
(10) Pub. No.: US 2026/0353529 A1
(43) Pub. Date: Nov. 5, 2026

(54) CCT CONTROLLABLE LED FILAMENT ARRANGEMENT HAVING LED FILAMENTS WITH SAME LIGHT-SOURCE OFF-STATE COLOUR APPEARANCE

(71) Applicant: SIGNIFY HOLDING B.V., EINDHOVEN (NL)

(72) Inventors: TIES VAN BOMMEL, HORST (NL); LAMBERT JOHANNES STIL, HELMOND (NL); RIFAT ATA MUSTAFA HIKMET, EINDHOVEN (NL)

(21) Appl. No.: 19/117,992

(22) PCT Filed: Oct. 2, 2023
(86) PCT No.: PCT/EP2023/077228

§ 371 Date: Apr. 3, 2025

(30) Foreign Application Priority Data
Oct. 4, 2022 (EP) 22199471.8

(51) Int. Cl. H05B 45/20; F21K 9/232; F21K 9/238; F21V 23/04; F21Y 103/10; F21Y 115/10; H05B 47/155; H05B 47/19; H10H 29/85; H10H 29/851; H10H 29/853

(52) U.S. Cl. CPC H05B 45/20; F21K 9/232; F21K 9/238; F21V 23/045; H05B 47/155; H05B 47/19; H10H 29/8508; H10H 29/8513; H10H 29/8514; H10H 29/853; F21Y 2103/10; F21Y 2115/10

(57) ABSTRACT

The present disclosure describes a light emitting diode, LED, filament arrangement (100) for providing arrangement light, the LED filament arrangement (100) comprising a first LED filament (110) configured to emit first LED filament light with a first correlated colour temperature, CCT1, a second LED filament (160) configured to emit second LED filament (160) light with a second correlated colour temperature, CCT2, and a controller (210) for individually controlling the first LED filament light emitted by the first LED filament (110) and the second LED filament (160) light emitted by the second LED filament (160) such that the arrangement light is variable in correlated colour temperature. The present disclosure also describes a LED filament lamp (220) comprising the LED filament arrangement (100) where the LED filament lamp (220) further comprises an envelope (230) at least partly enclosing the first and second LED filament (160), and a cap (240) for electrically and mechanically connecting the LED filament lamp (220) to a socket of a luminaire. The present disclosure also describes a luminaire (250) comprising a LED filament arrangement (100) or a LED filament lamp (220).

### FIELD OF THE INVENTION

The present invention generally relates to LED filament arrangements. In particular, the present invention relates to LED filament arrangements for providing light with a tunable correlated colour temperature.

### BACKGROUND OF THE INVENTION

The technical field of illumination has seen a rapid development with the introduction of new technologies, such as light emitting diodes, LEDs. The area is under continuous transformation and continues to attract attention. Compared to traditional light sources such as incandescent lamps, fluorescent lamps, neon tube lamps, etc., arrangements or devices comprising LEDs provide numerous advantages such as an increased flexibility and control, a more compact design, and/or a reduced power consumption. In particular, traditional light sources are rapidly being replaced by LED-based lighting solutions.

Arrangements or devices, such as LED filament lamps or luminaires, may be employed in order to provide light with a tunable correlated colour temperature, CCT. A device with a tunable CCT may be obtained by providing a plurality of LED filaments, where each LED filament is configured to provide light with a different CCT. A problem with the above is that the device will comprise different LED filaments with different off-state colours, and thus appear visually unpleasing.

Hence, it is an object of the present invention to provide a lighting arrangement that mitigates said shortcomings.

WO 2020/260197 relates to a lighting device that comprises a first elongated LED filament and a second elongated LED filament. The lighting device further comprises an at least partially light-transmissive envelope, which at least partially envelops at least the first LED filament and the second LED filament, and a base on which the at least partly light-transmissive envelope is mounted. The first LED filament is configured to emit light with a different color temperature than the second LED filament. Further, the second LED filament is at least partially curved such that it defines at least part of a contour of a volume. The first LED filament is arranged at least partially within the volume.

### SUMMARY OF THE INVENTION

A first aspect of the present invention provides a light emitting diode, LED, filament arrangement for providing arrangement light, the LED filament arrangement comprising a first LED filament configured to emit first LED filament light with a first correlated colour temperature, CCT1, the first LED filament comprising a first carrier, a plurality of first LEDs arranged on the first carrier, wherein each first LED is configured to emit first LED light with a first peak wavelength, λ1, and a first encapsulant encapsulating the plurality of first LEDs and at least partly covering the first carrier, wherein the first encapsulant comprises a first luminescent material configured to at least partly convert first LED light into first converted light and wherein the first encapsulant has a first light-source off-state colour appearance, A1, a second LED filament configured to emit second LED filament light with a second correlated colour temperature, CCT2, the second LED filament comprising a second carrier, a plurality of second LEDs arranged on the second carrier, wherein each second LED is configured to emit second LED light with a second peak wavelength, λ2, and a second encapsulant encapsulating the plurality of second LEDs and at least partly covering the second carrier, wherein the second encapsulant comprises a second luminescent material configured to at least partly convert the second LED light into second converted light and wherein the second encapsulant has a second light-source off-state colour appearance, A2, and a controller for individually controlling the first LED filament light emitted by the first LED filament and the second LED filament light emitted by the second LED filament such that the arrangement light is variable in correlated colour temperature, wherein λ1 is in the range 430-494, wherein λ2=487+/−7 nm, wherein CCT1≤CCT2−500K, and wherein A1 and A2 are the same.

The LED filament arrangement may be employed in order to provide arrangement light with a tunable CCT, where the LED filaments of the LED filament arrangement have the same off-state colour appearance. λ1 in the range 430-494 and λ2=487+/−7 nm have been found based on testing to allow for generation of melanopic light while at the same time providing arrangement light with a high CCT. The LED filament arrangement also enables the use of similar materials as the first and second encapsulant, and thus enables the LED filaments of the LED filament arrangement to have the same off-state colour appearance.

In an embodiment of the invention λ1=450+/−20 nm, λ2=487+/−7 nm and λ2−λ1≥20 nm. Use of these specific wavelengths enables similar phosphors and phosphor ratio to be used and thus enables the LED filaments of the LED filament arrangement to have the same off-state colour appearance. Use of these specific wavelengths yields a favourable light quality, as two different types of blue light may be used, and also enables controllable melanopic light to be created while at the same time providing arrangement light with a high CCT.

In another embodiment of the invention λ1=487+/−7 nm, and λ2=487+/−7 nm. Using these specific wavelength ranges is favourable as it enables the first and second luminescent material be similar or the same material and thus enables the LED filaments of the LED filament arrangement to have the same off-state colour appearance. Using these specific wavelength ranges enables both the first LEDs filament and the second LED filament to emit white light within a broad range of correlated colour temperatures, and also enables melanopic light to be produced at low CCTs.

In yet another embodiment of the invention the first encapsulant has a first thickness, T1, and a first luminescent material concentration, C1, wherein the second encapsulant has a second thickness, T2, and a second luminescent material concentration, C2,wherein T2≤0.8T1 and/or wherein C2≤0.8C1. The obtained effect is that the CCT1 and CCT2 may be chosen to differ in order to provide arrangement light with a tunable CCT.

In yet another embodiment of the invention the first luminescent material comprises a green and/or a yellow phosphor, and a red phosphor, and the second luminescent material comprises a green and/or a yellow phosphor, and a red phosphor. The luminescence by the first and second luminescent material may thus be chosen in order to at least in part determine CCT1 and CCT2.

In yet another embodiment of the invention the green and/or yellow phosphor of the first and second luminescent material are the same, and optionally the red phosphor of the first and second luminescent material are the same. The obtained effect is here that the first LED filament and the second LED filament obtains light-source off-state colour appearance.

In yet another embodiment of the invention the green and/or yellow phosphor has a lower excitation intensity at the second peak wavelength, λ2, than at the first peak wavelength, λ1. The excitation intensity of the first and second luminescent material may be chosen in order to at least in part determine a difference between CCT1 and CCT2 such that the CCT of the arrangement light may be adjusted.

In yet another embodiment of the invention a difference in excitation intensity at the first and second peak wavelength is at least 20% of the peak excitation intensity of the green and/or yellow phosphor. The excitation intensity by the first and second luminescent material may thus be of certain magnitude such that CCT1 and CCT2 may differ.

In yet another embodiment of the invention CCT1≤2500K and CCT2>2700K, preferably CCT1 is in the range 800-2400K. Said difference between CCT1 and CCT2 enables a large variation of the CCT of the arrangement light.

In yet another embodiment of the invention the arrangement light is configured to be adjusted between a third correlated colour temperature, CCT3, and a fourth correlated colour temperature, CCT4, wherein CCT3≤2500K and CCT4≥2700K, and CCT3≤CCT4−500K. Said difference between CCT3 and CCT4 has been found by the investors to be preferable in a wide range of applications, such as in LED filament lamp and luminaires.

In yet another embodiment of the invention CCT1≤2300K, CCT3≤2300K, CCT2≥3000K and CCT4≥3000K. Said difference between CCT3 and CCT4 has been found by the investors to be preferable in a wide range of applications, such as in LED filament lamp and luminaires.

In yet another embodiment of the invention any one or more of the first luminescent material and the second luminescent material comprises a luminescent material of the type A3B5O12:Ce, wherein A comprises one or more of Y, La, Gd, Tb and Lu, and wherein B comprises one or more of Al, Ga, In and Sc; and wherein the arrangement light is white light having a correlated colour temperature in the range 1800-6500 K and a colour rendering index of at least 80. This choice of first luminescent material and second luminescent material enables a high excitation probability and a desirable wavelength distribution of converted light.

In yet another embodiment of the invention any one or more of the first luminescent material and the second luminescent material comprises a KSiF phosphor. This choice of first luminescent material and second luminescent material enables a high excitation probability and a desirable wavelength distribution of converted light.

A second aspect of the present invention provides LED filament lamp comprising an LED filament arrangement, the LED filament lamp further comprising an envelope at least partly enclosing the first and second LED filament, and a cap for electrically and mechanically connecting the LED filament lamp to a socket of a luminaire, and further comprising an antenna for wirelessly controlling the controller. The LED filament lamp may be employed in order to provide light with a tunable CCT and where the LED filaments of the LED filament lamp have the same off-state colour appearance.

A third aspect of the present invention provides luminaire comprising an LED filament arrangement or a LED filament lamp. The luminaire may be employed in order to provide light with a tunable CCT and where the LED filaments of the luminaire have the same off-state colour appearance.

### BRIEF DESCRIPTION OF THE DRAWINGS

This and other aspects of the present invention will now be described in more detail, with reference to the appended drawings showing embodiment(s) of the invention.

FIG. 1 schematically illustrates an LED filament arrangement that comprises a first LED filament, a second LED filament and a controller,

FIG. 2 schematically illustrates a first LED filament and a second LED filament, where each LED filament comprises a carrier, a plurality of LEDs and an encapsulant, where the thickness of the encapsulant of the first LED filament is thinner than the thickness of the encapsulant of the second LED filament,

FIG. 3 schematically illustrates an LED filament lamp comprising an LED filament arrangement,

FIG. 4 schematically illustrates the relative intensity of a first LED a second LED and a blue LED as well as the excitation spectra of a YAG: Ce type phosphor,

FIG. 5 schematically illustrates CIE colour space chromaticity diagram where the correlated colour temperature of a first LED filament and the correlated colour temperature of a second LED filament is shown, and

FIG. 6 schematically illustrates a luminaire comprising an LED filament arrangement.

### DETAILED DESCRIPTION

In the following, general embodiments as well as particular exemplary embodiments of the invention will be described. References will be made to the accompanying drawings. It shall be noted, however, that the drawings are exemplary embodiments only, and that other features and embodiments may well be within the scope of the invention as claimed. Further, the mentioning of references such as “a” or “an” etc. should not be construed as excluding a plurality, and the term “disclosure” may herein be used interchangeably with the term “invention”.

Unless otherwise defined, all terms of art, notations and other scientific terms or terminology used herein are intended to have the meanings commonly understood by those of skill in the art to which this invention pertains. Certain terms of art, notations, and other scientific terms or terminology may, however, be defined specifically as indicated below.

The present invention relates to an LED filament arrangement, an LED filament lamp comprising the LED filament arrangement, and a luminaire comprising the LED filament arrangement.

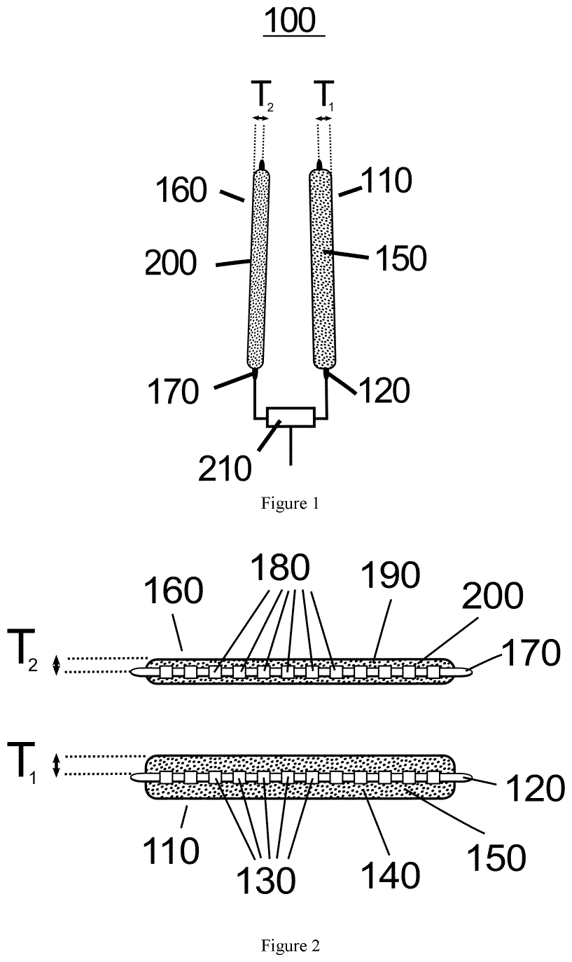

Referring to FIG. 1, the LED filament arrangement 100 comprises according to the present invention a first LED filament 110, a second LED filament 160 and a controller 210. The first LED filament 110 and the second LED filament 160 may as illustrated be connected to the controller 210, for example via a direct or indirect electronic connection.

The first LED filament is configured to emit first LED filament light with a first correlated colour temperature, CCT1, and the second LED filament is configured to emit second LED filament light with a second correlated colour temperature, CCT2. The controller is configured to individually control the first LED filament light and the second LED filament light such that the LED filament arrangement as a whole may emit arrangement light. By controlling intensity and correlated colour temperature of the first and second LED filament light, the correlated colour temperature, CCT, of the arrangement light may be varied. The controller may itself for example be pre-programed or be itself controlled via a for example an external switch, an external control unit, or similar. The controller may for example comprise or be connected to an antenna for wirelessly communicating with an external controller unit.

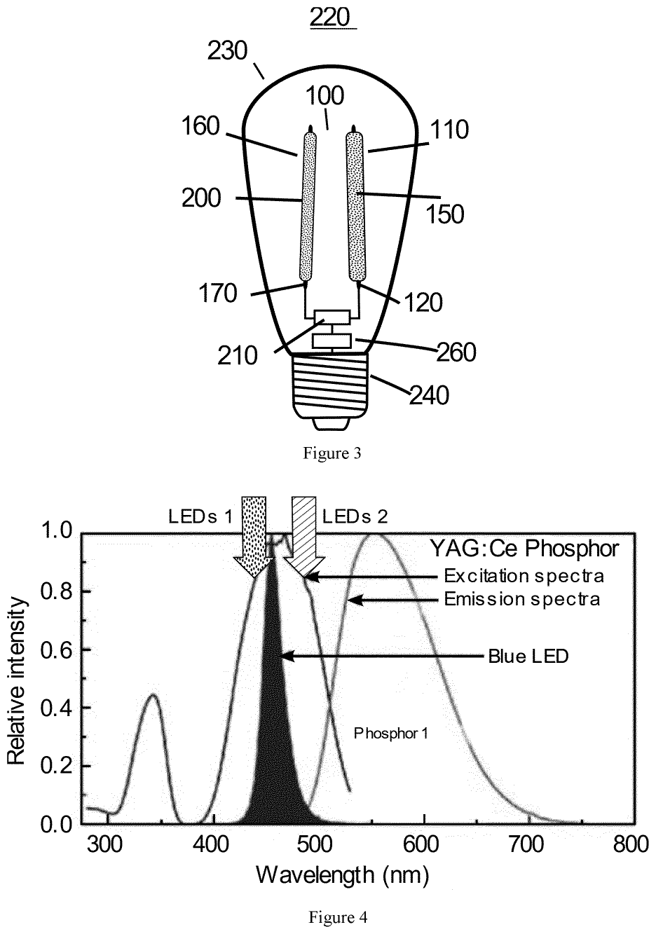

Referring to FIGS. 2 and 3, the first LED filament 110 comprises according to the present invention a first carrier 120, a plurality of first LEDs 130 and a first encapsulant 140, while the second LED filament 160 comprises a second carrier 170, a plurality of second LEDs 180 and a second encapsulant 190. The plurality of first and second LEDs 130, 180 are arranged on the first and second carrier 120, 170 respectively, for example periodically. The encapsulant 140, 190 of each filament 110, 160 is arranged such that it encapsulates the plurality of LEDs 130, 180 arranged on the carrier 120, 170 of said filament 110, 160 and such that it at least partly covers the carrier 120, 170. An LED 130, 180 arranged on an LED filament 110, 160 may herein be considered encapsulated by an encapsulant if any light emitted by said LED will have had to pass through the encapsulant 140, 190 before escaping the LED filament 110, 160. An LED 130, 180 on a carrier 120, 170 and encapsulated by an encapsulant 140, 190 may thus generally be in contact with the carrier 120, 170 and the encapsulant 140, 190. The first LED filament may in a particular embodiment only comprise first LEDs. The second LED filament may in a particular embodiment only comprise second LEDs.

Each carrier 120, 170 may as schematically illustrated in FIG. 1 or 2 be an elongated body, for example with a length in the longitudinal direction in the range ~1 cm and a width in the transverse direction in the range ~1 mm. The plurality of first and second LEDs 130, 180 are arranged on the first and second carrier 120, 170 respectively, for example with an even spacing along the longitudinal direction of an elongated body of the relevant carrier 120, 170. For each carrier 120, 170, the plurality of LEDs 130, 180 may be connected to electrical power via the carrier 120, 170, for example via one or more electrical conductors of the carrier 120, 170 or by the carrier 120, 170 itself acting as a conductor. It will be appreciated by a person skilled in the art with knowledge of the present disclosure that any one or both of the first and second carrier 120, 170 may take on a variety of shapes and that the arrangement of LEDs 130, 180 on either carrier 120, 170 may vary. Any one or both of the first carrier 120 and the second carrier 170 may for example be shaped as a helix, a loop, etc.

The first and second encapsulant may according to the present invention comprise a first luminescent material and a second luminescent material respectively. The first luminescent material is configured to at least partly convert first LED light into first converted light, and the second luminescent material is configured to at least partly convert second LED light into second converted light. Each luminescent material may here absorb at least part of the LED light from the LEDs it encapsulates and re-emit converted light in the form of luminescent radiation. The intensity and wavelength distribution of any converted light emitted by an encapsulant may depend both on the properties of the LED light emitted by the encapsulated LEDs and on the properties of the encapsulant. Said properties of the LED light may here comprise any one or more intensity and wavelength distribution. Said properties of the encapsulant may here comprise any one or more of the thickness, transmission properties, and excitation intensity of the encapsulant. FIG. 4 schematically illustrates the relative intensity of a blue LED as well as the excitation spectra of a YAG: Ce type encapsulant. The excitation spectra can here be seen to be shifted relative to the wavelength distribution of the blue led. First LED light and second LED light may as schematically illustrated in FIG. 4 have a peak wavelength λ1 and λ2, where λ1=440 nm and λ2=487 nm.

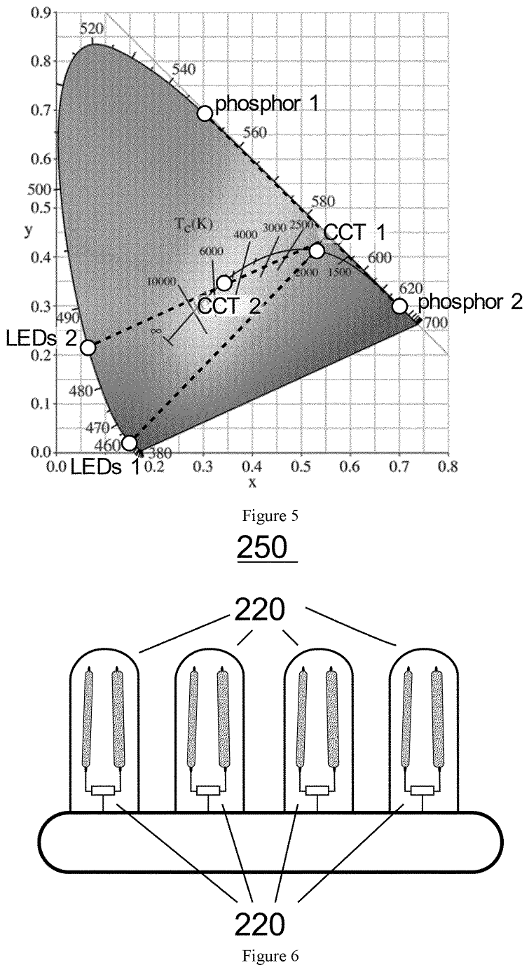

The excitation intensity of the first and second encapsulant may depend i.a. on the first luminescent material concentration, C1, and second luminescent material concentration, C2, respectively. C1 and C2 may thus be chosen in order to at least in part determine the amount of first converted light and second converted light respectively. According to a particular embodiment of the present disclosure the first luminescent material concentration may be larger than the second luminescent material concentration. More preferably, the first luminescent material concentration and the second luminescent material concentration may be chosen such that C2≤0.8C1. The latter may enable a larger amount of first converted light relative to second converted light and will shift the first filament light towards the right of the CIE colour space chromaticity diagram relative to the second filament light. The latter is visualized in FIG. 5.

The light emitted by a LED filament will according to the present disclosure be a combination of LED light and converted light. The CCT of the light emitted by an LED filament may thus be selected by choosing any one or more parameters that affects the LED light or the conversion properties of the encapsulant. Similarly, the arrangement light emitted by the LED filament arrangement is a combination of the first LED filament light and the second LED filament light. The arrangement light may thus be chosen by defining any one or more parameter that affects any one or more of the first LED light, the second LED light, the conversion properties of the first encapsulant and the conversion properties of the second encapsulant. The CCT of the LED filament arrangement consequently depends on CCT1, CCT2 as well as the intensity of the first and second LED filament light.

According to the present invention, each first LED is configured to emit first LED light with a first peak wavelength, λ1, and each second LED is configured to emit second LED light with a second peak wavelength, λ2. λ1 may here be different from λ2. Each first LED may generally be an LED configured to emit first LED light with a first peak wavelength, λ1 in the range 430-494 nm, while each second LED may generally be an LED configured to emit second LED light with a second peak wavelength, λ2=487+/−7 nm. Each first LED may in other words be configured to emit light in the blue-cyan-range, while each second LED may be configured to emit cyan light. The term peak wavelength may be used interchangeably with the term dominant wavelength. λ2 is preferably chosen such that λ2=487+/−6 nm, more preferably λ2=487+/−5 nm, and most preferably, 487+/−4 nm.

In an embodiment of the invention, λ1=450+/−20 nm, and λ2−λ1≥20 nm. Said wavelengths have been found to allow generation of melanopic light while at the same time providing arrangement light with a high CCT. Melanopic light may be considered as light in wavelength range 475-500 nm. A difference between 1 and λ2 of at least 20 nm, i.e. λ2−λ1≥20 nm, is particularly preferable for achieving an arrangement light with both a high CCT and with additional melanopic light. In a preferred embodiment λ2−λ1≥25 nm, more preferably≥30 nm, and most preferably≥35 nm. For λ1 it is preferred that λ1=450+/−15 nm, more preferable λ1=450+/−12 nm and most preferably λ1=445+/−10 nm.

In a particular embodiment of the invention λ1=487+/−7 nm and λ2=487+/−7 nm. Choosing λ1=487+/−7 nm and λ2=487+/−7 nm enables both the first LED and the second LEDs to emit the same light. The first and second luminescent material may be the same material, for example may the first and second luminescent material comprise the same ratio between a green and a red phosphor, or alternatively the same ratio between a yellow and red phosphor. A1 and A2 may thus be the same. The thickness and/or concentration of phosphor may be different between the first LED filament and the second LED filament in order to provide a difference between the CCT1 and CCT2. Choosing λ1=487+/−7 nm and λ2=487+/−7 nm enables both the first LEDs filament and the second LED filament to emit white light within a broad range of correlated colour temperatures.

A difference between λ1 and λ2 may, as schematically visualized in FIG. 5, contribute to the first LED filament light having a CCT1, and the second LED filament light having a CCT2. The controller may thus be employed in order to adjust the intensity of the first LEDs and intensity of the second LEDs in order to adjust the ratio between the first LED filament light with CCT1 and the second LED filament light having a CCT2. The controller may consequently be employed in order to adjust the CCT of the arrangement light, as the combination of the first LED filament light and the second LED filament light makes up the arrangement light. The intensity of the either of the first and/or second LEDs may here be adjusted for example by adjusting the power delivered to the first and/or second LEDs.

The difference between CCT1 and CCT2 may generally according to the present invention be chosen such that CCT1≤CCT2−500K. Said difference is preferred in order to provide a minimum tuning of the CCT of the LED filament arrangement. Preferably CCT1≤CCT2−1000K, more preferably CCT1≤CCT2−1500K and most preferably CCT1≤CCT2−2000K.

The CCT1 and CCT2 may in a particular embodiment of the present invention be chosen such that CCT1≤2500K and CCT2≥2700K. The arrangement light may configured to be adjusted between a third correlated colour temperature, CCT3, and a fourth correlated colour temperature, CCT4. The CCT3 and CCT4 may be chosen such that CCT3≤2500K, CCT4≥2700K, and CCT3≤(CCT4−500K). In another embodiment CCT1, CCT2, CCT3 and CCT4 may be chosen such that CCT1≤2300K, CCT3≤2300K, CCT2≥3000K and CCT4≥3000K.

With reference to FIG. 2, the first encapsulant 140 may have a first thickness, T1, and the second encapsulant 190 may have a second thickness, T2. The thickness of any encapsulant 140, 190 may here be understood as the thickness of the encapsulant 140, 190 on any LED 130, 180, i.e. that the thickness of the encapsulant 140, 190 is the shortest distance which the light from an encapsulated LED 130, 180 of a filament 110, 160 will have to travel in the encapsulant 140, 190 before said light may exit the filament 110, 160. According to an embodiment of the present invention, T1 and T2 may be chosen such that T2≤0.8T1. Such a thickness difference has been found to enable adequate tuning of the CCT of the arrangement light.

The first and second encapsulant may according to the present disclosure have a first and second light-source off-state colour appearance respectively. The first and second light-source off-state colour appearance may herein generally be referred to as A1 and A2. The light-source off-state colour appearance of any encapsulant may for example be determined by the fluorescence and reflectance of said encapsulant. A light-source off-state colour appearance of an encapsulant may for example be defined by the peak wavelength of the light emerging from said encapsulant. Using the latter definition, A1 and A2 may herein be defined as being the same if the peak wavelength of the light emerging from the first encapsulant in the off-state is within 15 nm, preferably 10 nm, of the peak wavelength of the light emerging from the second encapsulant. A light-source off-state colour appearance of an encapsulant may alternatively be defined using CIE xy-parameters. Using the latter definition, A1 and A2 may herein be defined as being the same if x_{A1}=x_{A2}±1.0 and y_{A1}=y_{A2}±1.0, A1 and A2 may alternatively be defined as being the same if x_{A1}=x_{A2}±0.5 and y_{A1}=y_{A2}±0.5. A1 may alternatively be considered as the same as A2 when first and the second encapsulant have the same color, typically orange. The first and the second encapsulant may additionally also have the same shade of color, more especially they may have the same colorfulness, chroma and/or saturation.

Any one or more of the first and second luminescent material may according to an embodiment of the invention each comprise a green and/or yellow phosphor, and a red phosphor. In other words, any one or more of the first and second luminescent material may each comprise a green phosphor and a red phosphor, a yellow phosphor and a red phosphor, or a green phosphor, yellow phosphor and a red phosphor. The green and/or yellow phosphor of the first luminescent material and the green and/or yellow phosphor of the first luminescent material may be different or the same. The red phosphor of the first luminescent material and the red phosphor of the second luminescent material may additionally or optionally be different or the same. The green and/or yellow phosphor may for example have a lower excitation intensity at λ2, than at λ1. The difference in excitation intensity at the first and second peak wavelength may in a particular embodiment be at least 20% of the peak excitation intensity of the green and/or yellow phosphor.

Any one or more of the first luminescent material and the second luminescent material may according to an embodiment of the present invention comprise a luminescent material of the type A₃B₅O₁₂:Ce. A may here comprises one or more of Y, La, Gd, Tb and Lu, B may comprise one or more of Al, Ga, In and Sc, and O is oxygen. Any one or more of the first luminescent material and the second luminescent material may as a way of example comprise an yttrium aluminium garnet, Y₃Al₅O₁₂, or a gadolinium aluminium garnet Gd₃Al₅O₁₂. In another example, the first luminescent material and/or the second luminescent material may comprise a KSiF phosphor. In another example, the first luminescent material and/or the second luminescent material may comprise a LuAG phosphor. It will be appreciated by a person skilled in the art with knowledge of the present invention that the first luminescent material and the second luminescent material may be chosen, optionally in combination with λ1 and λ2, in order to determine the correlated colour temperature range in which the LED filament arrangement may be varied. The arrangement light may generally according to any embodiment of the present invention be white light having a correlated colour temperature in the range 1800-6500 K and a colour rendering index of at least 80.

The LED, filament arrangement 100 may generally be a part of an LED light bulb, LED filament lamp 220, luminaire 250 etc. FIG. 3 schematically illustrates an LED filament lamp 220 comprising the LED filament arrangement 100. The LED filament lamp 220 may here further comprise an envelope 230 at least partly enclosing the first and second LED filament 110, 160, and a cap 240 for electrically and mechanically connecting the LED filament lamp 220 to a socket, for example of a luminaire 250. The envelope 230 may here be a transparent material such as a transparent ceramic, or a polymer. The cap 240, also sometimes referred to as a base, may for example be an Edison screw, e.g. an E27, E14 or similar. FIG. 6 schematically illustrates a luminaire 250 comprising the LED filament arrangement 100. As will be appreciated by a person skilled in the art, the luminaire 250 may take on a wide variety of shapes. The luminaire may as schematically illustrated in FIG. 6 comprise a plurality of LED filament arrangements 100.

A LED filament lamp 220 or luminaire may as schematically illustrated in FIG. 3 generally further comprising an antenna 260. The antenna may here be configured to wirelessly communicate with an external control unit or similar in order to provide instruction to the controller 210 of the filament arrangement 100. The antenna 260 may thus be considered as configured to control the controller 210.

1. A light emitting diode, LED, filament arrangement for providing arrangement light, the LED filament arrangement comprising:
a first LED filament configured to emit first LED filament light with a first correlated color temperature, CCT1, the first LED filament comprising:
a first carrier,
a plurality of first LEDs arranged on the first carrier, wherein each first LED is configured to emit first LED light with a first peak wavelength, λ1, and
a first encapsulant encapsulating the plurality of first LEDs and at least partly covering the first carrier, wherein the first encapsulant comprises a first luminescent material configured to at least partly convert first LED light into first converted light and wherein the first encapsulant has a first light-source off-state color appearance, A1,
a second LED filament configured to emit second LED filament light—with a second correlated color temperature, CCT2, the second LED filament comprising
a second carrier,
a plurality of second LEDs arranged on the second carrier, wherein each second LED is configured to emit second LED light with a second peak wavelength, λ2, and
a second encapsulant-encapsulating the plurality of second LEDs and at least partly covering the second carrier, wherein the second encapsulant comprises a second luminescent material configured to at least partly convert the second LED light into second converted light—and wherein the second encapsulant has a second light-source off-state color appearance, A2, and;
a controller for individually controlling the first LED filament light emitted by the first LED filament and the second LED filament light emitted by the second LED filament such that the arrangement light is variable in correlated color temperature;
wherein λ1 is in the range 430-470 nm, λ2=487+/−7 nm and λ2−λ1≥20 nm, wherein CCT1≤CCT2−500K, and wherein A1 and A2 are the same.

2. The LED filament arrangement according to claim 1, wherein CCT1≤CCT2−1000 K.

3. (canceled)

4. The LED filament arrangement according to claim 1, wherein the first encapsulant has a first thickness, T1, and a first luminescent material concentration, C1, wherein the second encapsulant has a second thickness, T2, and a second luminescent material concentration, C2, wherein T2≤0.8T1 and/or wherein C2≤0.8C1.

5. The LED filament arrangement according to claim 1, wherein the first luminescent material comprises a green and/or a yellow phosphor, and a red phosphor, and wherein the second luminescent material comprises a green and/or a yellow phosphor, and a red phosphor.

6. The LED filament arrangement according to claim 5, wherein the green and/or yellow phosphor of the first and second luminescent material are the same, and optionally wherein the red phosphor of the first and second luminescent material are the same.

7. The LED filament arrangement according to claim 5, wherein the green and/or yellow phosphor has a lower excitation intensity at the second peak wavelength, λ2, than at the first peak wavelength, λ1.

8. The LED filament arrangement according to claim 5, wherein a difference in excitation intensity at the first and second peak wavelength is at least 20% of the peak excitation intensity of the green and/or yellow phosphor.

9. The LED filament arrangement according to claim 1, wherein CCT1≤2500K and CCT2≥2700K preferably wherein CCT1 is in the range 800-2400K.

10. The LED filament arrangement according to claim 1, wherein the arrangement light is configured to be adjusted between a third correlated color temperature, CCT3, and a fourth correlated color temperature, CCT4, wherein CCT3≤2500K and CCT4>2700K, and CCT3≤(CCT4−500K).

11. The LED filament arrangement according to claim 10, wherein CCT1≤2300K, CCT3≤2300K, CCT2≥3000K and CCT4>3000K.

12. The LED filament arrangement according to claim 1, wherein any one or more of the first luminescent material and the second luminescent material comprises a luminescent material of the type A3B5O12:Ce, wherein A comprises one or more of Y, La, Gd, Tb and Lu, and wherein B comprises one or more of Al, Ga, In and Sc; and wherein the arrangement light is white light having a correlated color temperature in the range 1800-6500 K and a color rendering index of at least 80.

13. The LED filament arrangement according to claim 1, wherein any one or more of the first luminescent material and the second luminescent material comprises a KSiF phosphor.

14. An LED filament lamp comprising the LED filament arrangement according to claim 1, the LED filament lamp further comprising an envelope at least partly enclosing the first and second LED filament, and a cap for electrically and mechanically connecting the LED filament lamp to a socket of a luminaire, and further comprising an antenna for wirelessly controlling the controller.

15. A luminaire comprising the LED filament arrangement according to claim 1.
